(19) United States
(12) Patent Application Publication
(10) Pub. No.: US 2026/0015713 A1
(43) Pub. Date: Jan. 15, 2026

(54) PLASMA ENHANCED NUCLEATION LAYER FORMATION

(71) Applicant: Applied Materials, Inc., Santa Clara, CA (US)

(72) Inventors: Shiyu YUE, Santa Clara, CA (US); Sahil Jaykumar PATEL, Sunnyvale, CA (US); Jiajie CEN, San Jose, CA (US); Wei LEI, San Jose, CA (US); Ju Hyun OH, San Jose, CA (US); Kuixin ZHU, Santa Clara, CA (US); Yu LEI, Belmont, CA (US)

(21) Appl. No.: 19/243,488

(22) Filed: Jun. 19, 2025

Related U.S. Application Data
(60) Provisional application No. 63/670,889, filed on Jul. 12, 2024.

(51) Int. Cl. C23C 16/02; C23C 16/08; C23C 16/50; C23C 16/52

(52) U.S. Cl. CPC C23C 16/0281; C23C 16/08; C23C 16/50; C23C 16/52

(57) ABSTRACT

Embodiments of the disclosure include apparatus and methods for plasma enhanced nucleation layer formations. A molybdenum-containing precursor (MCP) is injected into a processing chamber at a processing temperature less than or equal to 450 degrees Celsius. A plasma is generated from a precursor gas that includes hydrogen, or a reduction gas. A molybdenum nucleation layer is formed on a substrate within the processing chamber using the plasma and the MCP. A layer of molybdenum is deposited over the molybdenum nucleation layer.

### CROSS-REFERENCE TO RELATED APPLICATIONS

This application claims benefit of U.S. Provisional patent application Ser. No. 63/670,889, filed Jul. 12, 2024, which is herein incorporated by reference in its entirety.

### BACKGROUND

### Field

Embodiments described herein generally relate to metal deposition. More specifically, embodiments of the present disclosure relate to plasma enhanced nucleation layer formation.

### Description of the Related Art

Integrated circuits have evolved into complex devices that can include millions of transistors, capacitors, and resistors on a single chip. In the course of integrated circuit evolution, functional density (that is, the number of interconnected devices per chip area) has generally increased while geometry size (that is, the smallest component (or line) that can be created using a fabrication process) has decreased.

Microelectronic devices are fabricated on a semiconductor substrate as integrated circuits in which various conductive layers are interconnected with one another to permit electronic signals to propagate within the device. Examples of such devices include memory (for example, dynamic random access memory (DRAM)) and logic devices, including both planar and three-dimensional structures. Three-dimensional structures include fin field-effect transistor (finFET) or metal-oxide-semiconductor field-effect transistor (MOSFET) devices.

In a traditional middle-end-of-the-line (MEOL) contact junction formation process, a feature also referred to a cavity, a via, or a trench, is fabricated in the semiconductor substrate. MEOL contact junctions allow connections between front-end-of-the-line (FEOL) semiconductor structures and back-end-of-the-line (BEOL) interconnects. Contacts with a low resistivity are desirable in semiconductor devices. However, when MEOL contacts have high resistance, the contacts produce poor connections between the FEOL structures and the BEOL packaging interconnects, reducing the performance of the packaged semiconductor structures.

Because of its material properties including high conductivity, molybdenum is a desirable material for multiple applications in semiconductor device manufacturing. However, depositing molybdenum using a molybdenum-containing precursor (MCP) is challenging due to the etching property of the MCP. In applications at relatively low temperatures, the MCP may etch the molybdenum at a higher rate than it can be deposited (e.g., “net etch”).

Accordingly, there is a need in the art for a desirable technique that solves the problems described above.

### SUMMARY

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

Embodiments of the present disclosure provide a method that includes injecting a molybdenum-containing precursor (MCP) into a processing chamber at a processing temperature less than or equal to 450 degrees Celsius. A plasma is generated from a precursor gas that includes hydrogen or a reduction gas. A molybdenum nucleation layer is formed on a substrate within the processing chamber using the plasma and the MCP. A layer of molybdenum is deposited over the molybdenum nucleation layer.

Embodiments of the present disclosure provide an apparatus including a substrate disposed in a processing chamber. The apparatus includes one or more non-transitory computer readable media storing executable instructions that, when executed by at least one processor, cause the at least one processor to perform operations including maintaining a processing temperature within the processing chamber at less than or equal to 450 degrees Celsius. A molybdenum-containing precursor (MCP) is injected into the processing chamber. Hydrogen is flowed into the processing chamber. A plasma is generated in the processing chamber by ionizing the hydrogen. A molybdenum nucleation layer is formed on the substrate. A layer of molybdenum is deposited over the molybdenum nucleation layer.

### BRIEF DESCRIPTION OF THE DRAWINGS

So that the manner in which the above recited features of embodiments of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic plan view of a multi-chamber substrate processing system, in accordance with certain embodiments of the present disclosure.

FIG. 2 illustrates graphs of deposition characteristics, in accordance with certain embodiments of the present disclosure.

FIGS. 3A, 3B, 3C, 3D, and 3E illustrate examples of depositing molybdenum via conformal growth, in accordance with certain embodiments of the present disclosure.

FIGS. 4A, 4B, 4C, 4D, and 4E illustrate examples of depositing molybdenum for gap filling via selective bottom-up growth, in accordance with certain embodiments of the present disclosure.

FIG. 5 is a process flow diagram illustrating a method for forming a molybdenum nucleation layer, in accordance with certain embodiments of the present disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein relate to metal deposition processes. More specifically, embodiments described herein relate to plasma enhanced deposition processes that include the formation of metal nucleation layers. In some embodiments, the metal (e.g., molybdenum) deposition process includes disposing a substrate on a substrate support within a processing chamber to cause the substrate temperature during the plasma enhanced molybdenum deposition process to be maintained at a relatively low processing temperature, for example, less than 400 degrees Celsius. A molybdenum-containing precursor (MCP) is injected into the processing chamber by a precursor delivery system. In one or more embodiments, a plasma is formed from a precursor gas that includes hydrogen.

In various embodiments, a molybdenum nucleation layer is formed on a surface of the substrate using the MCP and the plasma as part of a plasma enhanced deposition process. It has been found that unlike using a thermal molybdenum deposition process that is performed at a relatively low temperature, which has a relatively small window for depositing molybdenum, the plasma enhanced deposition process described herein has a relatively large window at the relatively low processing temperature. Because of the improved deposition process efficiency found in the methods described herein, the molybdenum nucleation layer is formed on the surface of the substrate before the natural etch rate effect created by the exposure to an excess amount of the MCP becomes greater than the deposition rate of the deposition process. After the molybdenum nucleation layer is formed, additional molybdenum can be deposited on the substrate using either a thermal deposition process or a plasma enhanced deposition process. In addition to having the relatively large window for molybdenum deposition, the plasma enhanced deposition process may also improve electrical properties of the deposited film. For example, the plasma enhanced deposition process may improve an electrical conductivity of the deposited film by increasing grain size and lowering sheet resistance, as well as reducing impurities in the deposited film due to a more efficient de-chlorination process facilitated by the hydrogen plasma.

### Multi-Chamber Processing System Examples

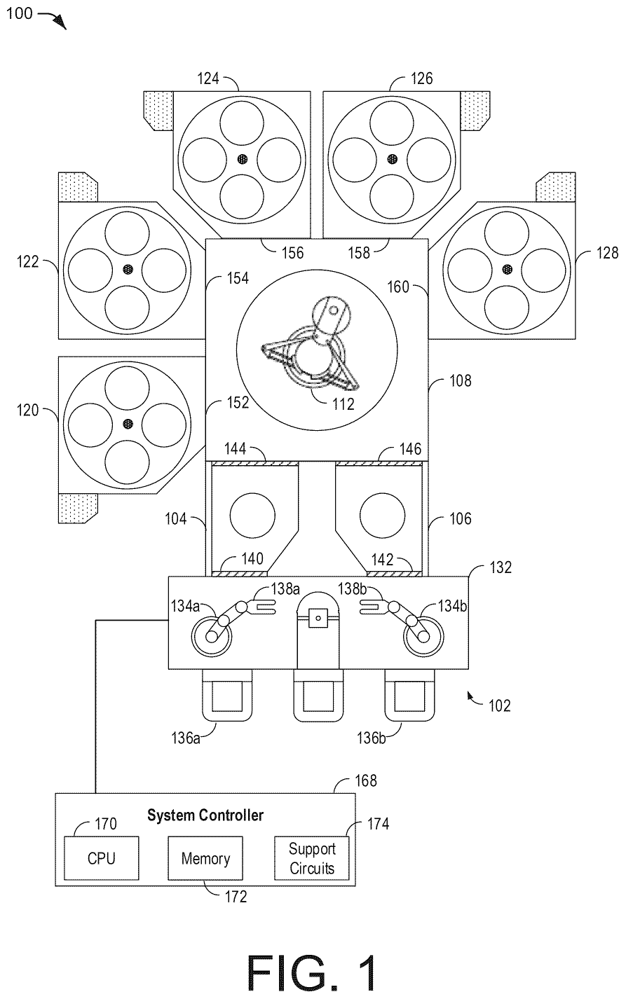

FIG. 1 is a schematic plan view of a multi-chamber substrate processing system 100. The substrate processing system 100 is capable of depositing a seamless fill of molybdenum from the bottom of a feature, upward to the top of the feature, without breaking vacuum. The substrate processing system 100 generally includes a factory interface 102, load lock chambers 104, 106, transfer chambers 108, a transfer robot 112, and processing chambers 120, 122, 124, 126, and 128.

Substrates in the substrate processing system 100 can be processed in and transferred between the various chambers without exposing the substrates to an ambient environment that is exterior to the substrate processing system 100. Furthermore, the substrates can be processed in and transferred between the various chambers maintained at a low pressure, or a vacuum environment without breaking the low pressure or vacuum environment. The substrate processing system 100 is capable of maintaining pressures between about 0.01 Torr to about 760 Torr. Accordingly, the substrate processing system 100 may provide for an integrated solution for processing of substrates.

Alternate examples of processing systems that may be suitably modified in accordance with the teachings provided herein include the Endura®, Producer®, or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In FIG. 1, the factory interface 102 includes a docking station 132 and factory interface robots 134a, 134b to facilitate transfer of substrates. The docking station 132 is configured to accept one or more front opening unified pods (FOUPs) 136a, 136b. In some examples, the factory interface robots 134a, 134b include blades 138a, 138b, respectively. The blades 138a, 138b are configured to transfer the substrates from the factory interface 102 to the load lock chambers 104, 106.

The load lock chambers 104, 106 have ports 140, 142, respectively, coupled to the factory interface 102 and ports 144, 146, respectively, coupled to the transfer chamber 108. The transfer chamber 108 includes ports 152, 154, 156, 158, 160 coupled to processing chambers 120, 122, 124, 126, 128, respectively. The ports 144, 146, 152, 154, 156, 158, 160 can be slit valve openings with slit valves for passing substrates through by the transfer robot 112. The ports 144, 146, 152, 154, 156, 158, 160 are configured to provide seals between respective chambers to prevent gases from passing between the respective chambers.

The load lock chambers 104, 106, the transfer chamber 108, and the processing chambers 120, 122, 124, 126, 128 may be fluidly coupled to a gas and pressure control system (not shown). The gas and pressure control system can include one or more gas pumps (e.g., turbo pumps, cryo-pumps, roughing pumps, etc.) gas sources, various valves, and conduits fluidly coupled to the load lock chambers 104, 106, the transfer chamber 108, and the processing chambers 120, 122, 124, 126, 128. In operation, the factory interface robots 134a, 134b transfer substrates from the FOUPs 136a, 136b through the ports 140, 142 to the load lock chambers 104, 106. The gas and pressure control system then pumps down the load lock chambers 104, 106. The gas and pressure control system further maintains the transfer chamber 108 with an interior low pressure or vacuum environment (which may include an inert gas). Hence, the pumping down of the load lock chambers 104, 106 facilitates passing substrates between, for example, the atmospheric environment of the factory interface 102 and the low pressure or vacuum environment of the transfer chamber 108.

With substrates in the load lock chambers 104, 106 that have been pumped down, the transfer robot 112 transfers the substrates from the load lock chambers 104, 106 into the transfer chamber 108 through the ports 144, 146. The transfer robot 112 is then capable of transferring the substrates to and/or between any of the processing chambers 120, 122, 124, 126, 128 through the ports 152, 154, 156, 158, 160, respectively, for processing. The transfer of the substrates within and among the various chambers can be in the low pressure or vacuum environment provided by the gas and pressure control system.

The processing chambers 120, 122, 124, 126, 128 include multiple processing stations disposed within a common processing region. The processing chambers 120, 122, 124, 126, 128 can be any appropriate chamber for processing a substrate. In some examples, the processing chamber 120 can be capable of performing an etch process, the processing chamber 122 can be capable of performing a cleaning process, and the processing chambers 126, 128 can be capable of performing respective growth (e.g., deposition) processes. The processing chamber 120 may be a Selectra™ Etch chamber available from Applied Materials of Santa Clara, California. The processing chamber 122 may be a SiCoNi™ Pre-clean chamber, or Volta™ chamber, available from Applied Materials of Santa Clara, California. The processing chamber 126, or 128, may be a Volta™ CVD/ALD chamber, or Encore™ PVD chambers available from Applied Materials of Santa Clara, California.

A system controller 168 is coupled to the substrate processing system 100 for controlling the substrate processing system 100 or components thereof. For example, the system controller 168 may control the operation of the substrate processing system 100 using a direct control of the processing chambers 120, 122, 124, 126, 128 of the substrate processing system 100 or by controlling controllers associated with the processing chambers 120, 122, 124, 126, 128. In operation, the system controller 168 enables data collection and feedback from the respective chambers to coordinate performance of the substrate processing system 100.

The system controller 168 generally includes one or more processors such as a central processing unit (CPU) 170, memory 172, and support circuits 174. The CPU 170 may be one of any form of a general-purpose processor that can be used in an industrial setting. In some embodiments, the memory 172 includes one or more non-transitory computer readable media storing executable instructions that, when executed by a processor, (such as the CPU 170) causes the processor to perform operations. The memory 172 is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. That is, the computer program product is tangibly embodied on the memory 172 (or non-transitory computer-readable medium or machine-readable storage device). When the computer instruction code is executed by the CPU 170, the CPU 170 controls the chambers to perform processes in accordance with the various methods.

The instructions in memory 172 may be in the form of a program product, such as a program that implements the methods of the present disclosure. In one example, the disclosure may be implemented as a program product stored on a computer-readable storage media for use with a computer system. The program(s) of the program product define functions of the embodiments (including the methods described herein). Thus, the computer-readable storage media, when carrying computer-readable instructions that direct the functions of the methods described herein, are embodiments of the present disclosure.

In particular embodiments, at least one of the processing chambers 120, 122 is a pre-clean chamber and at least one of the processing chambers 124, 126, 128 is a chemical vapor deposition (CVD) chamber. In operation, a substrate having a feature formed therein may be transferred to a first processing chamber which is one of the processing chambers 122, 124 where the feature is exposed to a pretreatment process to remove, or clean, for example, native oxides formed on the feature. The substrate may then be transferred to a second processing chamber which is one of the processing chambers 124, 126, 128 without breaking vacuum where a metal layer, for example, a molybdenum layer, is deposited over the feature. The substrate may then be transferred to a third processing chamber without breaking vacuum for additional processing. Other processing systems can be implemented in various embodiments.

### Nucleation Layer Formation Examples

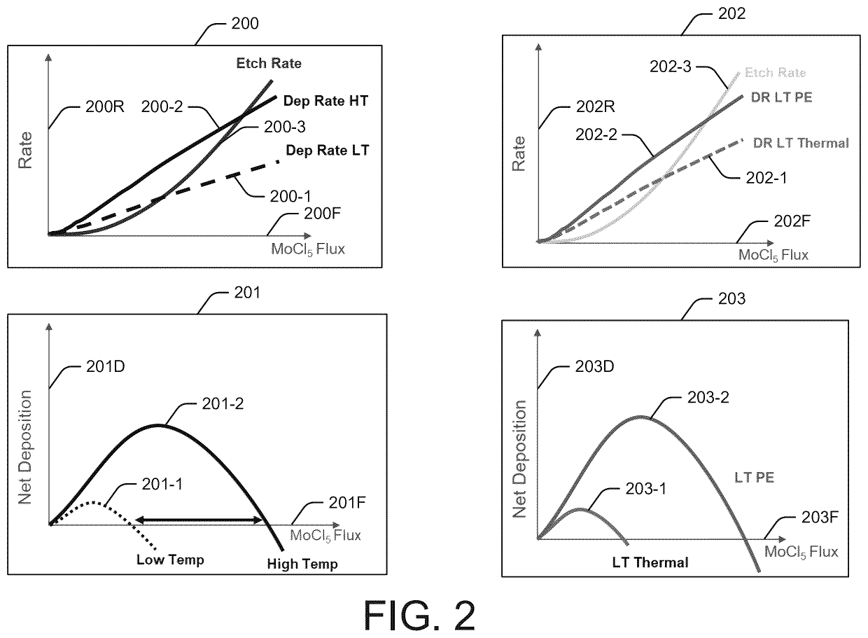

FIG. 2 illustrates graphs 200-203 of deposition characteristics used during one or more of the methods described herein. In the graph 200, the x-axis represents molybdenum-containing precursor (MCP) flux 200F and the y-axis represents deposition/etch rate 200R of molybdenum. A first curve 200-1 indicates a deposition rate of molybdenum at low temperatures (e.g., less than 400 degrees Celsius). A second curve 200-2 indicates a deposition rate of molybdenum at high temperatures (e.g., greater than 450 degrees Celsius). A third curve 200-3 indicates an etch rate of molybdenum by the exposure to the MCP which is generally temperature independent. As shown by the first curve 200-1 and the third curve 200-3, as the MCP flux 200F increases at the low temperatures, the etch rate of molybdenum by the MCP quickly becomes greater than the deposition rate of molybdenum. In some embodiments, when using molybdenum pentachloride (MoCl₅) as the MCP, the deposition and etch reactions can be written as follows:

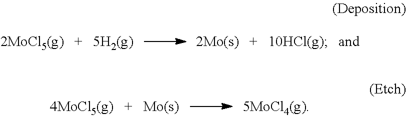

wherein hydrogen (H₂) is utilized a reducing agent during the deposition process and the etching reaction can occur while the reducing agent is absent or in the case where an excess of the molybdenum pentachloride (MoCl₅) at the surface of the substrate is present relative to the amount of the reducing agent.

In the graph 201, the x-axis represents MCP flux 201F and the y-axis represents the net deposition amount 201D of molybdenum. A first curve 201-1 indicates net deposition of molybdenum at low temperatures (e.g., less than 400 degrees Celsius). A second curve 201-2 indicates net deposition of molybdenum at high temperatures (e.g., greater than 450 degrees Celsius). As shown by the first curve 201-1, as the MCP flux 201F increases at the low temperatures, there is a relatively small window in which molybdenum can be deposited before the molybdenum etching reaction caused by the over exposure of the exposed molybdenum layer to the MCP effectively causes a net loss in the amount of molybdenum on the surface of the substrate. If a molybdenum nucleation layer does not form on the exposed surfaces of the substrate during the relatively small window of time, then it may take a significant amount of time (e.g., an incubation delay) for the molybdenum nucleation layer to form on the substrate. Notably, it is possible for the MCP to damage the underlying layers (e.g., dielectric layers) formed on the substrate during the incubation delay period before molybdenum is deposited on the substrate.

In the graph 202, the x-axis represents molybdenum-containing precursor (MCP) flux 202F and the y-axis represents deposition/etch rate 202R of molybdenum. A first curve 202-1 indicates a deposition rate of molybdenum at low temperatures (e.g., less than 400 degrees Celsius) using a thermal deposition process. In an example in which the MCP includes MoCl₅ and hydrogen is injected into a processing chamber for depositing molybdenum, then a reaction for the thermal deposition process will follow the deposition equation described above.

A second curve 202-2 indicates a deposition rate of molybdenum at the low temperatures using a plasma enhanced deposition process. In an example in which the MCP includes MoCl₅, hydrogen is injected into the processing chamber for depositing molybdenum, and the plasma that is enhancing the deposition process is generated using the hydrogen precursor, then a reaction for the plasma enhanced deposition process may be described as:

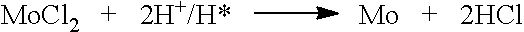

A third curve 202-3 indicates an etch rate of molybdenum by the exposure to the MCP which is generally temperature independent. As shown by the second curve 202-2 and the third curve 202-3, as the MCP flux 202F increases at the low temperatures, the deposition rate of molybdenum using the plasma enhanced deposition process is greater than the etch rate of molybdenum by the exposure to the MCP until the amount of the MCP flux 202F is too high.

In the graph 203, the x-axis represents the MCP flux 203F and the y-axis represents net deposition amount 203D of molybdenum. A first curve 203-1 indicates net deposition of molybdenum at low temperatures (e.g., less than 400 degrees Celsius) using the thermal deposition process. A second curve 203-2 indicates net deposition of molybdenum at the low temperatures using the plasma enhanced deposition process. As shown by the second curve 203-2, as the MCP flux 201F increases at the low temperatures, there is a relatively large window in which molybdenum can be deposited before the etch rate of molybdenum by the over exposure of the MCP effectively causes a net loss in the amount of molybdenum on the surface of the substrate.

The relatively large window significantly increases a likelihood that a nucleation layer forms quickly on a substrate such that molybdenum rapidly begins to deposit on the substrate. Unlike the example in the graph 201, the rapid deposition of molybdenum on the substrate using the plasma enhanced process prevents the MCP from damaging the substrate surface. The plasma enhanced deposition process may have further benefits in addition to preventing damage to the substrate surface such as improved electrical properties of deposited films. For example, depositing the films using the plasma enhanced deposition process may result in increased grain size and lower sheet resistance relative to the example in the graph 201. Notably, increasing the grain size and lowering the sheet resistance improves the electrical conductivity of the deposited films.

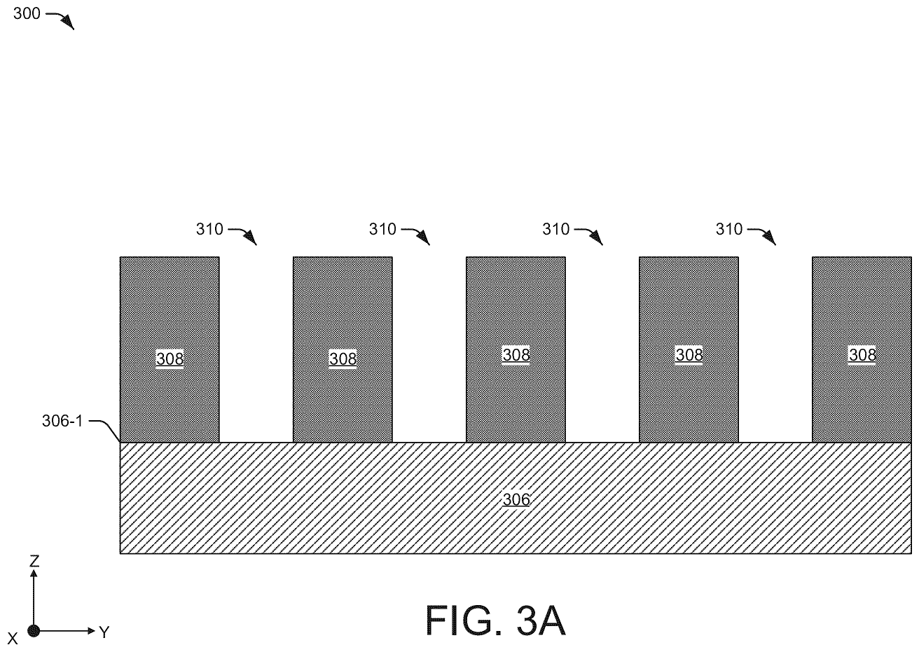

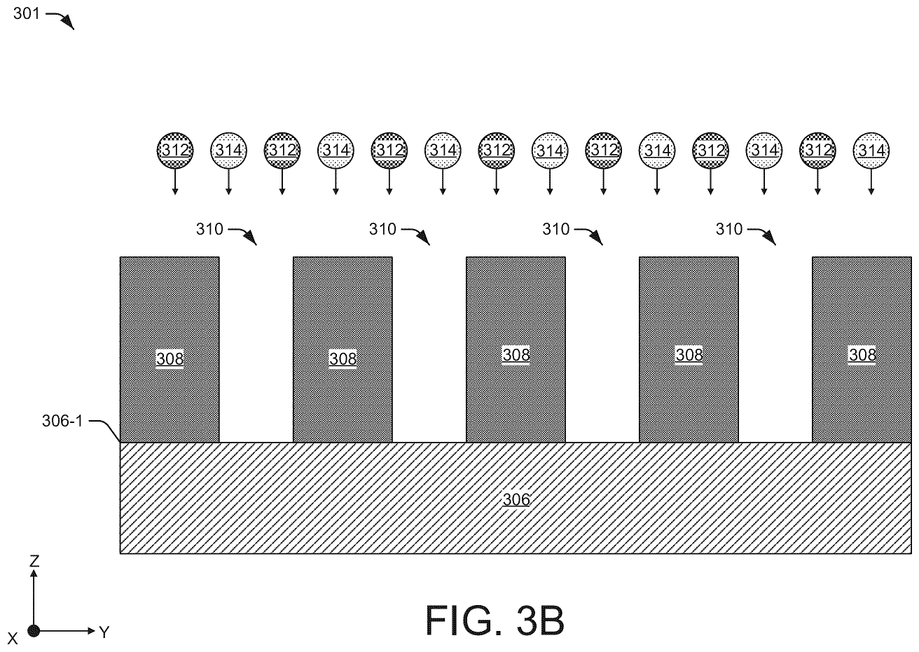

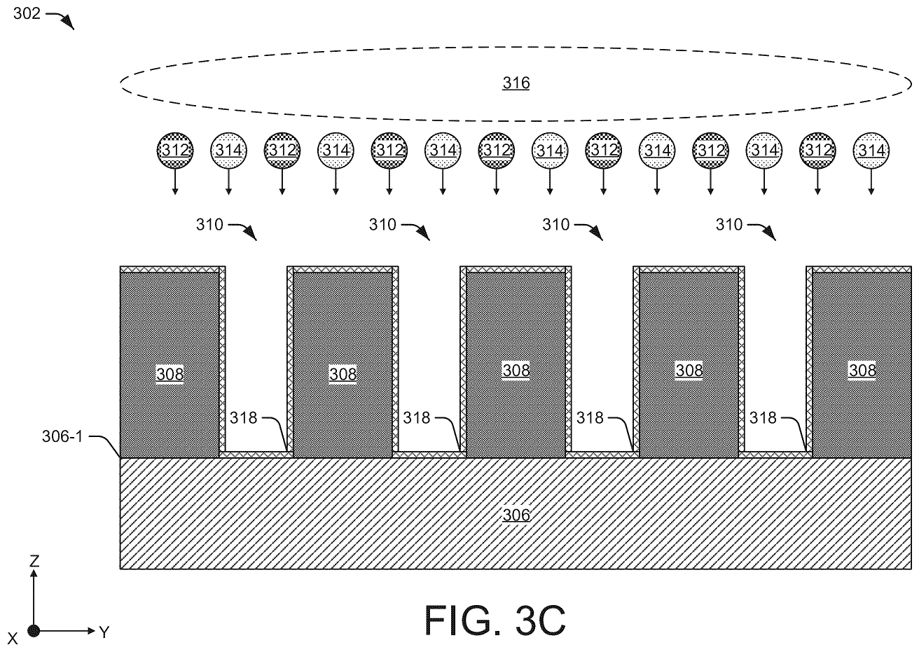

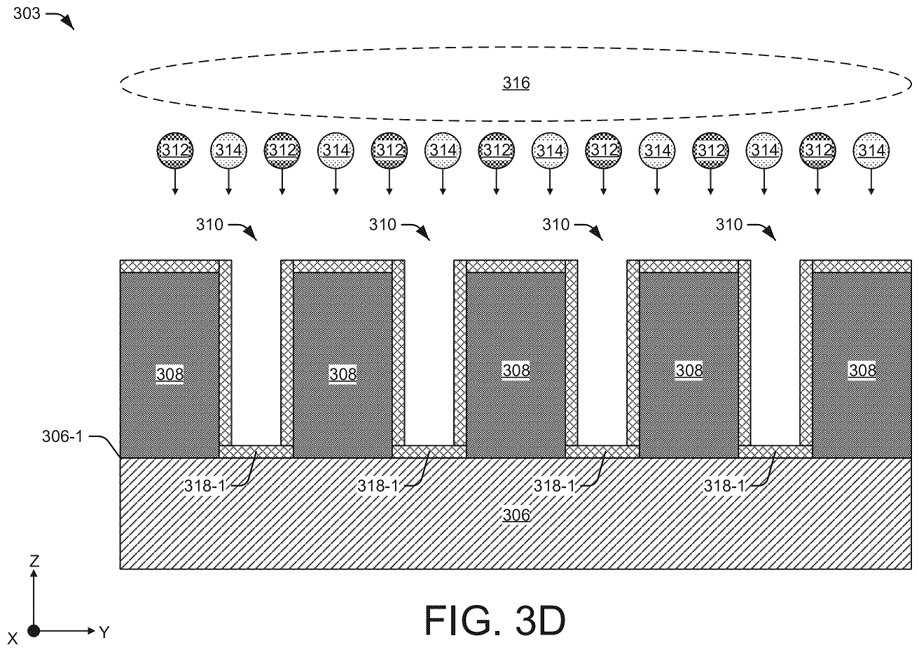

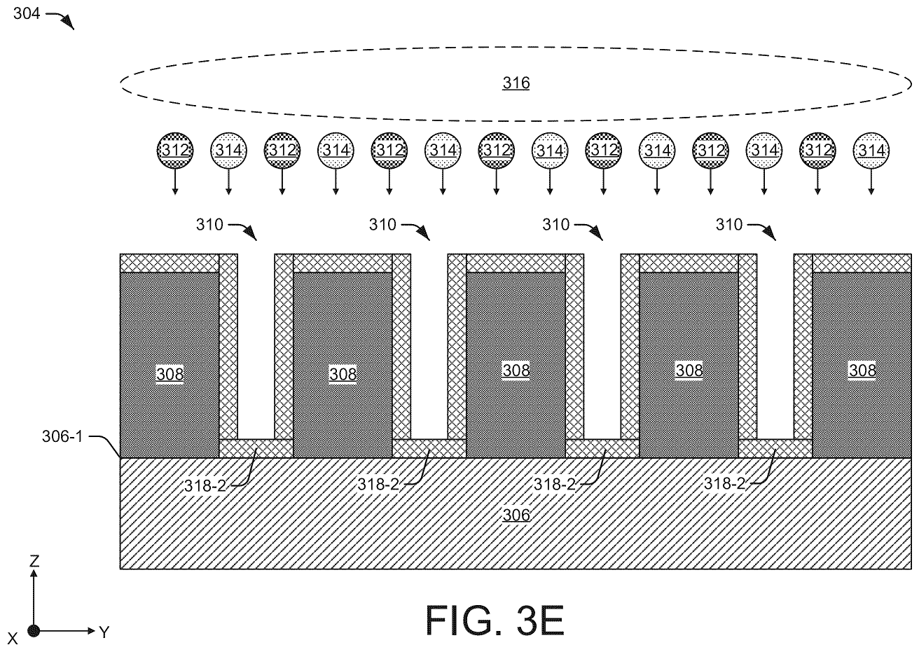

FIGS. 3A, 3B, 3C, 3D, and 3E illustrate examples of a process of depositing molybdenum via conformal growth. FIG. 3A is a schematic cross-sectional view 300 of a substrate 306. In various embodiments, the substrate 306 can include tungsten, cobalt, copper, titanium nitride, titanium aluminide, titanium silicon nitride, or other materials. The substrate 306 is disposed in a processing chamber such as one of the processing chambers 124, 126, 128 at a controlled temperature and pressure. In one or more embodiments, the processing chamber is a chemical vapor deposition (CVD) processing chamber, a pulsed chemical vapor deposition (P-CVD) with coflow processing chamber, an atomic layer deposition (ALD) processing chamber, a plasma enhanced atomic layer deposition (PEALD) processing chamber, a plasma enhanced chemical vapor deposition (PECVD) processing chamber, a chemical vapor deposition with post deposition plasma treatment (CVD+PL treatment) processing chamber, or another processing chamber utilizing one or more different deposition processes. In some embodiments, the processing temperature is in a range of 200 to 400 degrees Celsius (C) such as 350° C. In other embodiments, the temperature may be less than 200° C. or greater than 400° C. The pressure may be in a range of 0.5 to 50 Torr such as a range of 1 to 20 Torr. A dielectric material 308 is formed on a surface 306-1 of the substrate 306 such that portions of the dielectric material 308 are separated by features 310. In various embodiments, the features 310 may be vias, trenches, gaps, or other structures. For example, the features 310 have high aspect ratios.

FIG. 3B is a schematic cross-sectional view 301 of the substrate 306 with a molybdenum-containing precursor (MCP) 312 injected into the processing chamber by a precursor delivery system (not shown). In various embodiments, the MCP 312 can include MoCl₅, MoF₆, MoO₂Cl₂, Mo(CO)₅, or another MCP. In one or more embodiments, hydrogen 314 is flowed into the processing chamber by a gas delivery system (not shown). In one or more examples, the hydrogen 314 is not flowed into the processing chamber that includes the MCP 312. In some embodiments, a flowrate of the hydrogen into the processing chamber is constant. In other embodiments, the flowrate of the hydrogen into the processing chamber may be variable.

FIG. 3C is a schematic cross-sectional view 302 of the substrate 306 with a plasma 316 formed within or delivered to the processing chamber. In an example in which the plasma 316 is delivered to the processing chamber, the plasma 316 is formed in a separate chamber (not shown) that does not include the MCP 312. In some embodiments, the plasma 316 is formed within the processing chamber by ionizing the hydrogen 314 flowed into the processing chamber after the MCP 312 is injected. In other embodiments, the plasma 316 is formed by ionizing a hydrogen containing precursor and/or a reduction gas within the processing chamber, or in a separate chamber (not shown). In other embodiments, the plasma 316 is formed by ionizing a processing gas mixture that can include the MCP 312 and a hydrogen containing precursor within the processing chamber, or in a separate chamber (not shown). In various embodiments, the plasma 316 is generated using a capacitively-coupled-plasma (CCP) source, an indirect capacitively-coupled-plasma (IDCCP) source, a remote plasma source (RPS), an inductively couple plasma (ICP) source, microwave plasma or another plasma source. In some embodiments, the plasma 316 is used in the plasma enhanced deposition process (e.g., CVD or ALD) described with respect to the graphs 202, 203. Since the plasma enhanced deposition process has the relatively large window in which molybdenum can be deposited before the etch rate of molybdenum by the MCP 312 effectively prevents molybdenum deposition, a molybdenum nucleation layer 318 is formed on the surface 306-1 of the substrate 306 and on the dielectric material 308. In some embodiments, the molybdenum nucleation layer 318 forms on the dielectric material 308 rapidly enough to prevent the MCP 312 from damaging the dielectric material 308. For example, the molybdenum nucleation layer 318 may prevent damage to the dielectric material 308 directly or the molybdenum nucleation layer 318 can prevent damage to the dielectric material 308 by facilitating rapid deposition of molybdenum over the molybdenum nucleation layer 318 to prevent the MCP 312 from damaging the dielectric material 308.

FIG. 3D is a schematic cross-sectional view 303 of the substrate 306 with a first amount 318-1 of molybdenum deposited within the features 310. In some embodiments, the first amount 318-1 of molybdenum is deposited within the features 310 and over the dielectric material 308 using the plasma 316 and the plasma enhanced deposition process. In other embodiments, once the molybdenum nucleation layer 318 is formed, the thermal deposition process deposits molybdenum at a rate similar to the plasma enhanced deposition process and the first amount 318-1 of molybdenum is deposited within the features 310 and over the dielectric material 308 using the thermal deposition process (not shown). Regardless of the process utilized, the first amount 318-1 of molybdenum deposited over the dielectric material 308 prevents the MCP 312 and hydrogen containing plasma from damaging the dielectric material 308. In some examples, the first amount 318-1 of molybdenum that is deposited within the features 310 and over the dielectric material 308 is net molybdenum etched from the substrate 306 by the MCP 312.

In some embodiments, the first amount 318-1 of molybdenum is selectively deposited on a surface of the features 310, such as the exposed surfaces of the substrate 306 versus the exposed surfaces of the dielectric material 308. In this case, the molybdenum nucleation layer 318 is advantageously rapidly formed by use of a plasma enhanced process described herein so that the components of the MCP that will tend to attack and damage the exposed surfaces of the features 310 are minimized, such as the surfaces of the dielectric material 308. Subsequent deposition processes used to fill the features 310 can then be used to selectively deposit material on the formed molybdenum nucleation layer 318.

FIG. 3E is a schematic cross-sectional view 304 of the substrate 306 with a second amount 318-2 of molybdenum deposited within the features 310. In some embodiments, the second amount 318-2 of molybdenum is deposited within the features 310 using either the thermal deposition process or the plasma enhanced deposition process. Although the illustrated examples describe forming the molybdenum nucleation layer 318 on the surface 306-1 of the substrate 306 within the features 310, it is to be appreciated that the described systems and techniques for forming the molybdenum nucleation layer 318 apply equally to blanket deposition applications. For example, instead of forming the molybdenum nucleation layer 318 within the features 310, the molybdenum nucleation layer 318 is formed on a larger portion of the surface 306-1 and the second amount 318-2 of molybdenum is deposited on the larger portion of the surface 306-1.

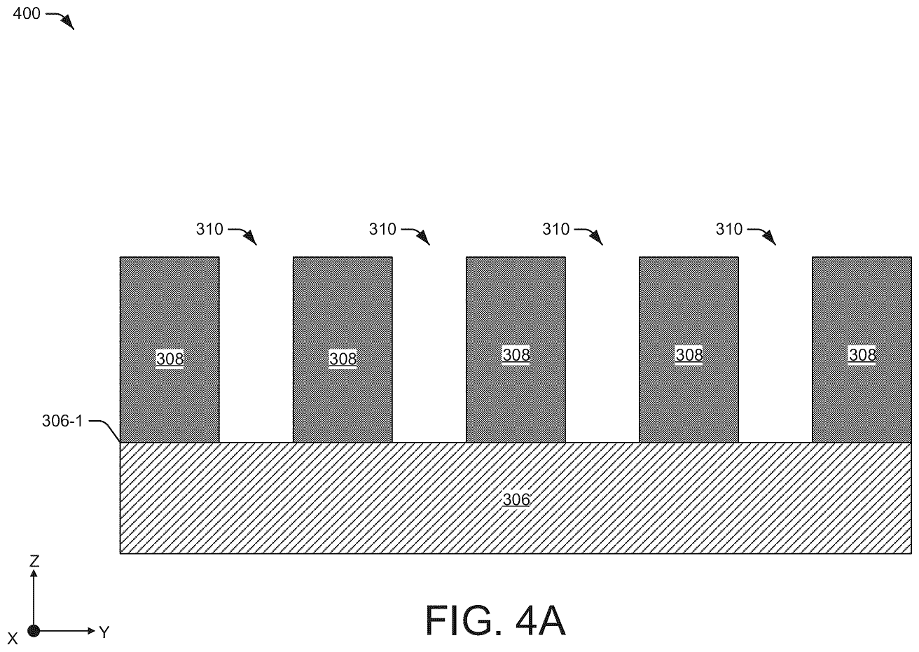

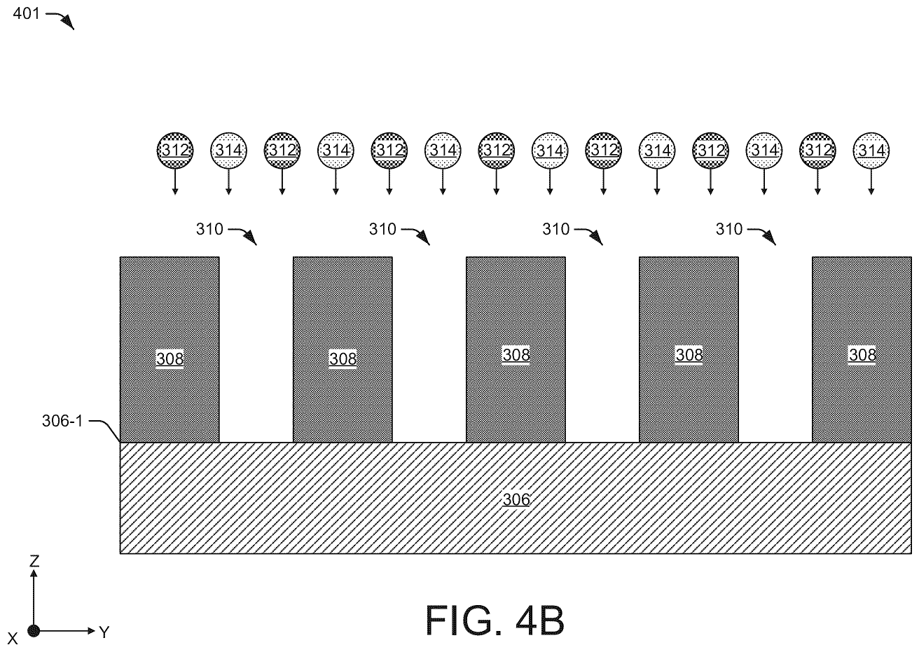

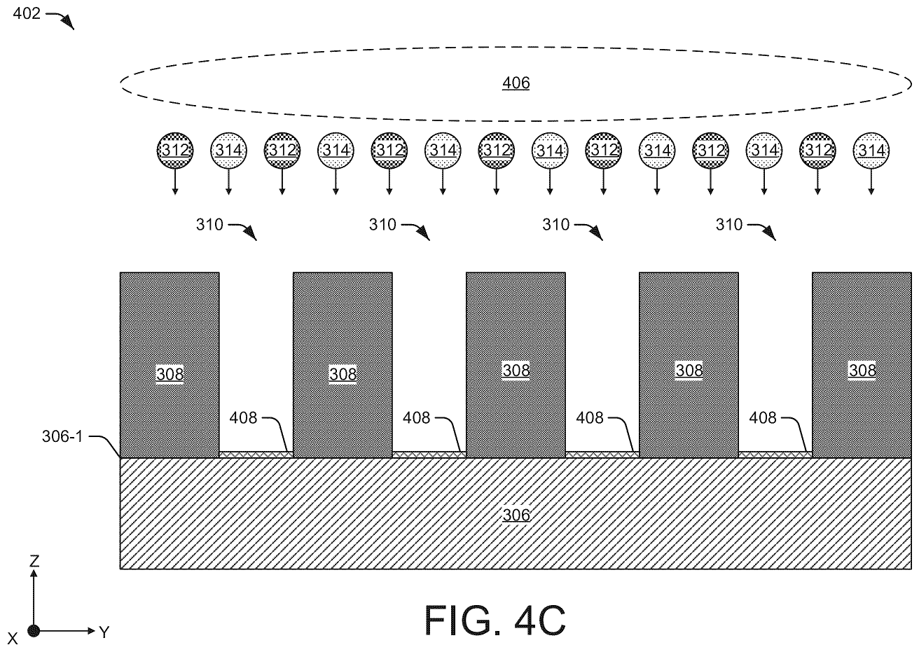

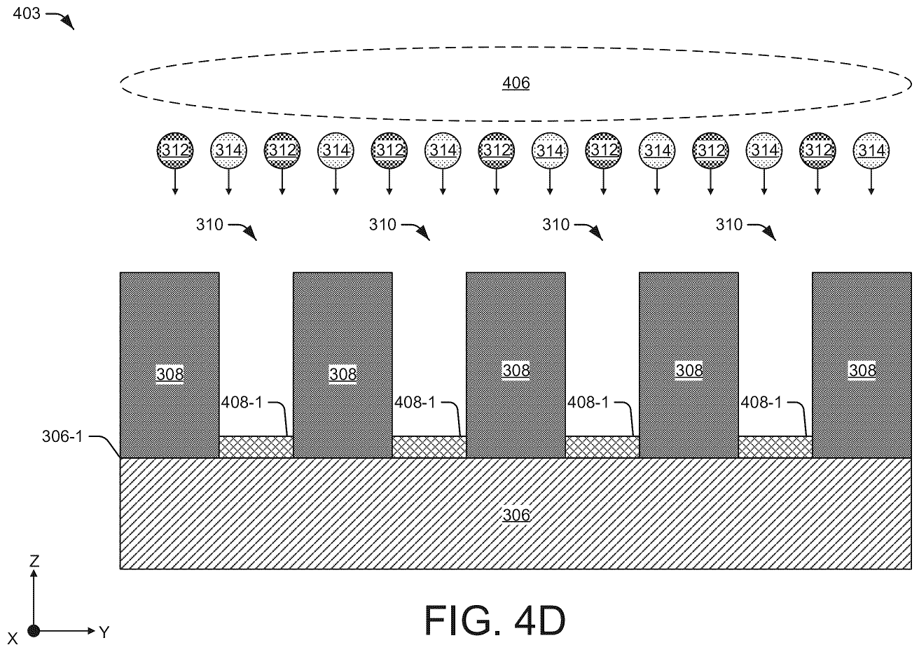

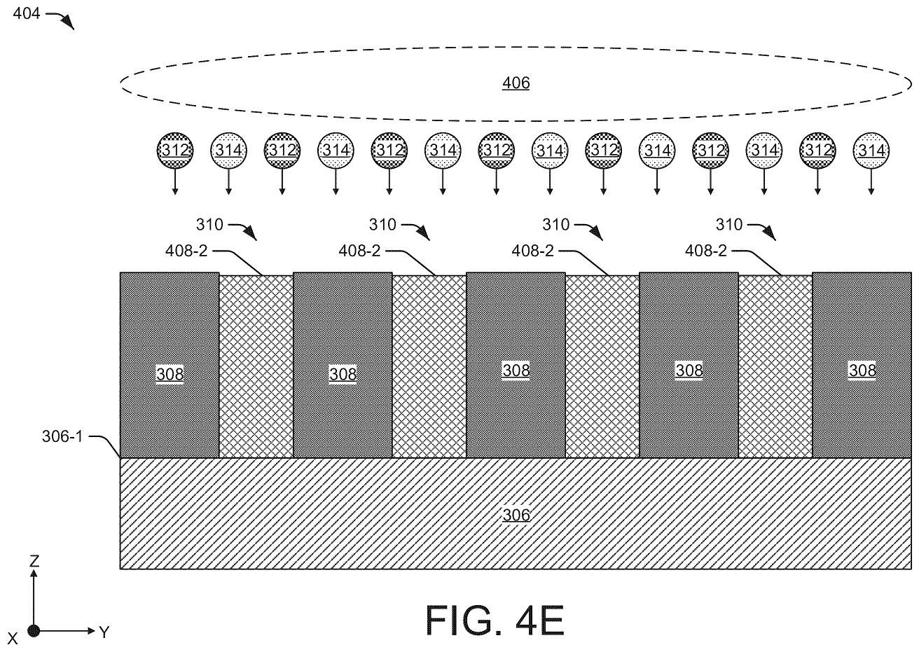

FIGS. 4A, 4B, 4C, 4D, and 4E illustrate examples of depositing molybdenum for gap filling via selective bottom-up growth. FIG. 4A is a schematic cross-sectional view 400 of the substrate 306. The dielectric material 308 is formed on the surface 306-1 of the substrate 306 such that portions of the dielectric material 308 are separated by the features 310 which can be vias, trenches, gaps, or other structures.

FIG. 4B is a schematic cross-sectional view 401 of the substrate 306 with the molybdenum-containing precursor (MCP) 312 injected into the processing chamber by the precursor delivery system (not shown). Hydrogen 314 is also flowed into the processing chamber by the gas delivery system (not shown).

FIG. 4C is a schematic cross-sectional view 402 of the substrate 306 with a plasma 406 formed within or delivered to the processing chamber. In some embodiments, the plasma 406 is formed within the processing chamber by ionizing the hydrogen 314. For example, the plasma 406 is used in the plasma enhanced deposition process described with respect to the graphs 202, 203. Since the plasma enhanced deposition process has the relatively large window in which molybdenum can be deposited before the etch rate of molybdenum by the MCP 312 effectively prevents molybdenum deposition, a molybdenum nucleation layer 408 is selectively formed on the surface 306-1 of the substrate 306.

FIG. 4D is a schematic cross-sectional view 403 of the substrate 306 with a first amount 408-1 of molybdenum deposited within the features 310. In some embodiments, the first amount 408-1 of molybdenum is selectively deposited within the features 310 using the plasma 406 as part of the plasma enhanced deposition process. In other embodiments, once the molybdenum nucleation layer 408 is formed, the thermal deposition process deposits molybdenum, and the first amount 408-1 of molybdenum is deposited within the features 310 using the thermal deposition process (not shown).

FIG. 4E is a schematic cross-sectional view 404 of the substrate 306 with a second amount 408-2 of molybdenum deposited within the features 310 via bottom-to-top gap filling. In some embodiments, the second amount 408-2 of molybdenum is selectively deposited within the features 310 using either the thermal deposition process or the plasma enhanced deposition process to fill the features 310. Notably, the plasma 406 (which can be hydrogen-based) is capable of providing a selectivity window between the substrate 306 (e.g., a metal substrate) and the dielectric material 308 in order to fill the features 310.

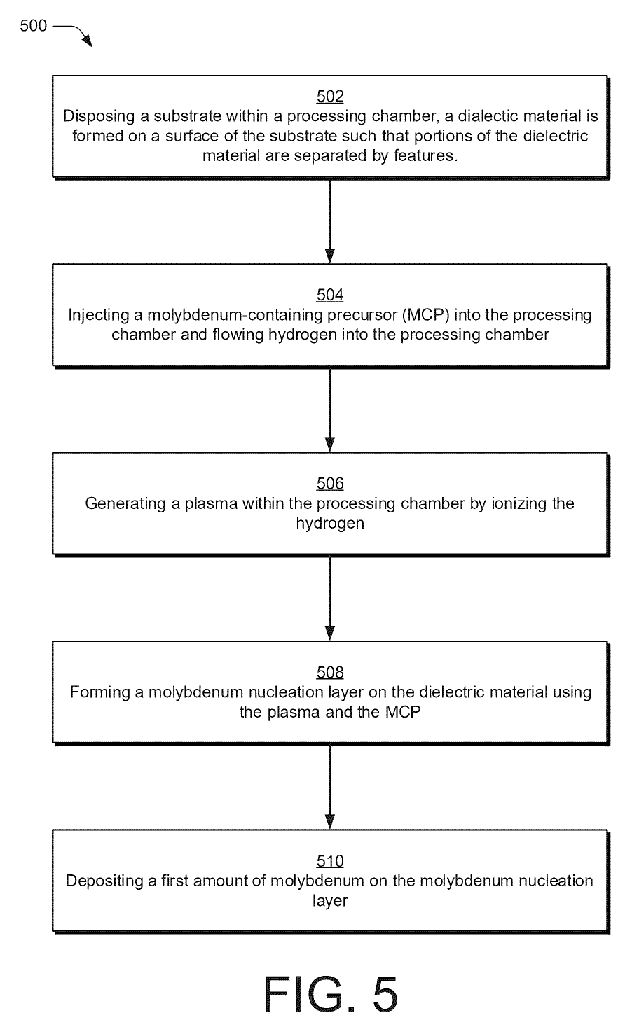

FIG. 5 is a process flow diagram illustrating a method 500 for forming a molybdenum nucleation layer. At operation 502, a substrate 306 is disposed within a processing chamber and a dielectric material 308 is formed on a surface 306-1 of the substrate 306 such that portions of the dielectric material 308 are separated by features 310.

At operation 504, a molybdenum-containing precursor (MCP) 312 is injected into the processing chamber and hydrogen 314 is flowed into the processing chamber.

At operation 506, a plasma 316 is generated within the processing chamber by ionizing the hydrogen 314.

At operation 508, a molybdenum nucleation layer 318 is formed on the dielectric material 308 using the plasma 316 and the MCP 312.

At operation 510, a first amount of molybdenum 318-1 is deposited on the molybdenum nucleation layer 318.

While the above description is directed to molybdenum for the sake of brevity, it is also contemplated that the plasma enhanced deposition process described herein may advantageously be used for other metals having similar deposition challenges (e.g., “net etch”). For example, the plasma enhanced deposition process may be used to increase the window for metal deposition and improve electrical properties of the deposited film for metals such as, but not limited to, molybdenum, tungsten, titanium, similar metals, or combinations thereof.

### Additional Considerations

In the above description, details are set forth by way of example to facilitate an understanding of the disclosed subject matter. It should be apparent to a person of ordinary skill in the field, however, that the disclosed implementations are exemplary and not exhaustive of all possible implementations. Thus, it should be understood that reference to the described examples is not intended to limit the scope of the disclosure. Any alterations and further modifications to the described devices, instruments, methods, and any further application of the principles of the present disclosure are fully contemplated as would normally occur to one skilled in the art to which the disclosure relates. In particular, it is fully contemplated that the features, components, and/or processes described with respect to one implementation may be combined with the features, components, and/or processes described with respect to other implementations of the present disclosure. As used herein, the term “about” may refer to a +/−10% variation from the nominal value. It is to be understood that such a variation can be included in any value provided herein.

As used herein, “a processor,” “at least one processor” or “one or more processors” generally refers to a single processor configured to perform one or multiple operations or multiple processors configured to collectively perform one or more operations. In the case of multiple processors, performance of the one or more operations could be divided amongst different processors, though one processor may perform multiple operations, and multiple processors could collectively perform a single operation. Similarly, “a memory,” “at least one memory” or “one or more memories” generally refers to a single memory configured to store data and/or instructions, multiple memories configured to collectively store data and/or instructions.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more operations or actions for achieving the described method. The method operations and/or actions may be interchanged with one another without departing from the scope of the claims. In other words, unless a specific order of operations or actions is specified, the order and/or use of specific operations and/or actions may be modified without departing from the scope of the claims.

While the foregoing is directed to embodiments of the present disclosure, other and further embodiments of the disclosure may be devised without departing from the basic scope thereof, and the scope thereof is determined by the claims that follow.

1. A method comprising:
injecting a molybdenum-containing precursor (MCP) into a processing chamber at a processing temperature less than or equal to 450 degrees Celsius;
generating a plasma from a precursor gas that includes hydrogen, or a reduction gas;
forming a molybdenum nucleation layer on a substrate within the processing chamber using the plasma and the MCP; and
depositing a metal containing layer over the molybdenum nucleation layer, wherein the metal containing layer comprises molybdenum.

2. The method of claim 1, wherein the molybdenum nucleation layer is formed on a dielectric material formed on a surface of the substrate.

3. The method of claim 2, further comprising filling vias formed between portions of the dielectric material formed on the surface of the substrate with molybdenum.

4. The method of claim 1, further comprising depositing the metal containing layer over the molybdenum nucleation layer using a thermal deposition process at the processing temperature less than or equal to 450 degrees Celsius.

5. The method of claim 1, further comprising depositing the metal containing layer over the molybdenum nucleation layer using the plasma.

6. The method of claim 1, wherein a pressure within the processing chamber is in a range of 0.5 to 50 Torr.

7. The method of claim 1, wherein the substrate includes at least one of tungsten, cobalt, copper, titanium nitride, titanium aluminide, or titanium silicon nitride.

8. The method of claim 1, wherein the processing temperature less than or equal to 450 degrees Celsius is greater than or equal to 200 degrees Celsius.

9. The method of claim 1, wherein the MCP includes at least one of MoCl₅, MoF₆, MoO₂Cl₂, or Mo(CO)₅.

10. The method of claim 1, wherein a flowrate of the precursor gas into the processing chamber is constant.

11. An apparatus comprising:
a processing chamber; and
one or more non-transitory computer readable media storing executable instructions that, when executed by at least one processor, cause the at least one processor to perform operations comprising:
maintaining a processing temperature within the processing chamber at less than or equal to 450 degrees Celsius;
injecting a molybdenum-containing precursor (MCP) into the processing chamber;
flowing a precursor gas comprising hydrogen into the processing chamber;
generating a plasma within the processing chamber by ionizing the precursor gas;
forming a molybdenum nucleation layer on a substrate disposed in the processing chamber; and
depositing a layer of molybdenum over the molybdenum nucleation layer.

12. The apparatus of claim 11, wherein the processing temperature within the processing chamber is maintained at greater than or equal to 200 degrees Celsius.

13. The apparatus of claim 11, wherein the substrate includes at least one of tungsten, cobalt, copper, titanium nitride, titanium aluminide, or titanium silicon nitride.

14. The apparatus of claim 11, wherein a pressure within the processing chamber is in a range of 1 to 20 Torr.

15. The apparatus of claim 11, wherein the MCP includes at least one of MoCl₅, MoF₆, MoO₂Cl₂, or Mo(CO)₅.

16. The apparatus of claim 11, wherein the molybdenum nucleation layer is formed on a dielectric material formed on a surface of the substrate.

17. The apparatus of claim 16, wherein vias formed between portions of the dielectric material formed on the surface of the substrate are filled with molybdenum.

18. The apparatus of claim 16, wherein the layer of molybdenum is deposited over the molybdenum nucleation layer using a thermal deposition process.

19. The apparatus of claim 16, wherein the layer of molybdenum is deposited over the molybdenum nucleation layer using the plasma.

20. The apparatus of claim 16, wherein the layer of molybdenum deposited over the molybdenum nucleation layer is net molybdenum etched from the substrate.
